(19) United States
(12) Patent Application Publication
(10) Pub. No.: US 2018/0351511 A1
(43) Pub. Date: Dec. 6, 2018

(54) ELECTRONIC DEVICE AND METHOD OF CONTROLLING DIGITALLY CONTROLLED CRYSTAL OSCILLATORS IN ELECTRONIC DEVICE

(71) Applicant: SAMSUNG ELECTRONICS CO., LTD., Suwon-si (KR)

(72) Inventors: In-Tae JUN, Daegu (KR); Jae-Young ROH, Gumi-si (KR); Mohammad SAQIB, Ghaziabad(U.P) (IN); Dae-Hwan LEE, Gumi-si (KR)

(21) Appl. No.: 15/992,943

(22) Filed: May 30, 2018

(30) Foreign Application Priority Data
Jun. 1, 2017 (KR) 10-2017-0068489

(51) Int. Cl. H03B 5/30; H03B 5/04; H03B 5/06

(52) U.S. Cl. CPC H03B 5/30; G01K 7/22; H03B 5/06; H03B 5/04

(57) ABSTRACT

Various embodiments associated with a DCXO installed in an electronic device are described. An electronic device may include: a frequency determining unit configured to determine a delta frequency corresponding to a difference between a first frequency for RF communication and a second frequency output from a frequency synthesis unit; a digitally-controlled crystal oscillator (DCXO) configured to comprise a plurality of capacitors including a first variable capacitor and a second variable capacitor, and an oscillator connected to the plurality of capacitors and outputting a clock; and a processor configured to change capacitances of the first variable capacitor and the second variable capacitor by applying a first control value to the first variable capacitor and applying a second control value to the second variable capacitor, based on the delta frequency. Other various embodiments may be possible.

### CROSS-REFERENCE TO RELATED APPLICATION

This application is based on, and claims priority under 35 U.S.C. § 119 to, Korean Patent Application No. 10-2017-0068489, filed on Jun. 1, 2017, in the Korean Intellectual Property Office, the disclosure of which is incorporated herein by reference in its entirety.

### BACKGROUND

### 1. Field

The present disclosure relates to a method of controlling digitally-controlled crystal oscillators (DCXO) by an electronic device.

### 2. Description of Related Art

Various mobile terminal type electronic devices, such as a cell phone, an MP3 player, a portable multimedia player (PMP), a tablet PC, Galaxy Tab, a smart phone, iPad, and an e-book reader, or the like, may provide various wireless communication services thanks to the development of telecommunications industry. The wireless communication services provided by electronic devices have been developed to diversify multimedia communication services which provide high-capacity data transmission services, such as video media services, Internet services, text information services, or the like, as well as voice communication services.

The electronic device generally includes a wireless transceiver for wireless communication, or may be coupled with a related wireless transceiver. The wireless transceiver may include a baseband processor, a radio frequency (RF) transceiver, and a local oscillator. The baseband processor may convert data to be transmitted according to a predetermined radio communication protocol into a baseband signal, and may convert a received baseband signal into data. The RF transceiver may convert a baseband signal to be transmitted into a transmission RF signal, and may demodulate a received RF signal into a baseband signal. The local oscillator may be a crystal oscillator, and may generate clock signals required when the RF transceiver performs signal conversion, using a reference frequency. For example, the RF transceiver may synchronize a carrier frequency with a base station or may synchronize time with the base station according to a clock signal, so as to transmit and receive an RF signal.

However, in a wireless communication environment, a reference frequency may need to be controlled according to various factors. For example, from the perspective of an external factor of an electronic device, when propagation delay occurs during signal transmission and reception with a base station, the electronic device has difficulty in synchronizing a frequency with the base station and thus, a reference frequency may need to be corrected. Also, from the perspective of an internal factor of the electronic device, the frequency of a crystal oscillator changes as the temperature of the electronic device changes, and thus, a reference frequency may need to be corrected.

### SUMMARY

Generally, an electronic device may perform an auto frequency correction (AFC) function using a device such as a temperature-compensated crystal oscillator (TCXO) and/or a digitally-controlled crystal oscillator (DCXO), so as to automatically correct a reference frequency. The AFC function may be a function that automatically performs compensation associated with a reference frequency that needs to be controlled based on various factors of a wireless communication environment. For example, the electronic device may perform an AFC function using the TCXO, thereby compensating for a change in the reference frequency of the crystal oscillator attributable to a change in the temperature of the electronic device. However, since the TCXO is large and expensive, the electronic device tends to adopt a DCXO which is relatively small and inexpensive compared to the TCXO, so as to perform an AFC function. The DCXO controls the reference frequency of a crystal oscillator according to a digital method.

When the electronic device uses the DCXO, the electronic device may additionally need a hardware element(s) (e.g., a thermistor and an analog digital converter (ADC)) for measuring temperature so as to compensate for a change in the frequency of the crystal oscillator attributable to a temperature change, and software for executing a temperature-based frequency correction algorithm.

Also, a temperature compensation table may be used for performing the temperature-based frequency correction algorithm. In this instance, a temperature compensation table may be different for each baseband platform, crystal oscillator model, and type of hardware. Accordingly, software and hardware need to be tuned for each case. Therefore, it takes a long time to develop an electronic device that uses the DCXO.

Also, in the case in which the DCXO needs to perform temperature-based frequency correction using the temperature compensation table, when a frequency that needs to be corrected exceeds the range of the temperature compensation table, the reference frequency may not be corrected. When the reference frequency correction is not corrected, the wireless transmission/reception function of the electronic device may malfunction.

Therefore, various embodiments provide an electronic device and a DCXO control method by the electronic device, whereby a reference frequency may be corrected using a DCXO as a temperature changes, without necessarily needing the hardware for measuring a temperature and the software for executing the temperature-based frequency correcting algorithm.

Also, various embodiments may provide an electronic device and a DCXO control method by the electronic device, whereby compensation may be automatically performed in association with a reference frequency that needs to be controlled based on various factors of the wireless communication environment, other than a temperature change.

According to various embodiments, an electronic device is provided, wherein the electronic device includes: a frequency determining unit, including frequency determining circuitry, configured to determine a delta frequency corresponding to a difference between a first frequency for RF communication and a second frequency output from a frequency synthesis unit which includes frequency synthesis circuitry; a digitally-controlled crystal oscillator (DCXO) configured to include a plurality of capacitors including a first variable capacitor and a second variable capacitor, and an oscillator connected to the plurality of capacitors and outputting a clock; and a processor configured to change capacitances of the first variable capacitor and the second variable capacitor by applying a first control value to the first variable capacitor and applying a second control value to the second variable capacitor, based on the delta frequency.

According to various embodiments, an electronic device is provided, wherein the electronic device includes: a frequency synthesis unit configured to output a reference frequency required for RF transmission/reception modulation; an RF transceiving module, including transceiving circuitry, configured to modulate/demodulate an RF transmission/reception signal; and a baseband module configured to convert data to be transmitted into a baseband signal, provide the baseband signal to the RF transceiving module, and convert a received RF signal into a baseband signal, wherein the RF transceiving module includes: a frequency determining unit configured to determine a delta frequency corresponding to a difference between a first frequency for RF communication and a second frequency output from the frequency synthesis unit; and a digitally-controlled crystal oscillator (DCXO) configured to include a plurality of capacitors including a first variable capacitor and a second variable capacitor, and an oscillator connected to the plurality of capacitors and outputting a clock, and the baseband module includes: a processor configured to change capacitances of the first variable capacitor and the second variable capacitor by applying a first control value to the first variable capacitor and applying a second control value to the second variable capacitor, based on the delta frequency.

According to various embodiments, a method of controlling a digitally-controlled crystal oscillator (DCXO) by an electronic device is provided, wherein the method includes: determining a delta frequency corresponding to a difference between a first frequency for RF communication and a second frequency output from a frequency synthesis unit; and changing capacitances of a first variable capacitor and a second variable capacitor by applying a first control value to the first variable capacitor and applying a second control value to the second variable capacitor, based on the delta frequency.

According to various embodiments, a storage medium for storing a program is provided, wherein the program in an electronic device performs: determining a delta frequency corresponding to a difference between a first frequency for RF communication and a second frequency outputted from a frequency synthesis unit; and changing capacitances of a first variable capacitor and a second variable capacitor by applying a first control value to a first variable capacitor and applying a second control value to a second variable capacitor, based on the delta frequency.

According to various embodiments, an electronic device may correct a reference frequency using a DCXO as a temperature changes, without a hardware element for measuring a temperature and software for executing a temperature-based frequency correction algorithm, whereby the manufacturing costs of the electronic device may be reduced and the structure of the hardware and software of the electronic device may be simplified.

Also, according to various embodiments, an electronic device may correct a reference frequency based on a temperature by tracking a delta frequency that needs to be corrected, instead of using a temperature compensation table, whereby the reference frequency may be corrected even when a frequency that needs to be corrected exceeds the range of the temperature compensation table.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a block diagram of a network environment including an electronic device according to various embodiments;

FIG. 2 is a block diagram of an electronic device according to various embodiments;

FIG. 3 is a block diagram of a program module according to various embodiments;

FIG. 4 is a block diagram illustrating a transceiving module and a baseband module in an electronic device according to various embodiments;

FIG. 5 is a conceptual diagram illustrating a circuit of a DCXO according to various embodiments;

FIG. 6 is a diagram illustrating a temperature compensation table according to various embodiments;

FIGS. 7A, 7B, and 8 are graphs illustrating a change in a frequency as a temperature changes, and a frequency correction range (dynamic range of AFC) according to various embodiments;

FIG. 9 is a diagram illustrating a table that compares DAC values between an existing frequency correction range (dynamic range of AFC) and a widened frequency correction range (widened dynamic range of AFC) according to various embodiments;

FIG. 10 is a graph illustrating the relationship between a DAC value and a delta frequency according to various embodiments;

FIG. 11 is a graph illustrating the relationship between a CDAC value, an AFCDAC value, and a compensation frequency in an electronic device according to various embodiments;

FIG. 12 is a diagram illustrating an operation of controlling a DCXO by an electronic device according to various embodiments;

FIG. 13 is a graph illustrating a section where compensation frequency values overlap as a CDAC value is changed in an electronic device according to various embodiments; and

FIG. 14 is a graph illustrating the case in which an electronic device removes a section where compensation frequency values overlap as a CDAC value is changed according to various embodiments.

### DETAILED DESCRIPTION

Hereinafter, various embodiments will be described with reference to the accompanying drawings. The embodiments and the terms used therein are not intended to limit the technology disclosed herein to specific forms, and should be understood to include various modifications, equivalents, and/or alternatives to the corresponding embodiments. In describing the drawings, similar reference numerals may be used to designate similar constituent elements. A singular expression may include a plural expression unless they are definitely different in a context. As used herein, singular forms may include plural forms as well unless the context clearly indicates otherwise. The expression “a first”, “a second”, “the first”, or “the second” used in various embodiments may modify various components regardless of the order and/or the importance but does not limit the corresponding components. When an element (e.g., first element) is referred to as being “(functionally or communicatively) connected,” or “directly coupled” to another element (second element), the element may be connected directly to the another element or connected to the another element through yet another element (e.g., third element).

The expression “configured to” as used in various embodiments may be interchangeably used with, for example, “suitable for”, “having the capacity to”, “designed to”, “adapted to”, “made to”, or “capable of” in terms of hardware or software, according to circumstances. Alternatively, in some situations, the expression “device configured to” may mean that the device, together with other devices or components, “is able to”. For example, the phrase “processor adapted (or configured) to perform A, B, and C” may mean a dedicated processor (e.g., embedded processor) only for performing the corresponding operations or a generic-purpose processor (e.g., Central Processing Unit (CPU) or Application Processor (AP)) that can perform the corresponding operations by executing one or more software programs stored in a memory device.

An electronic device according to various embodiments may include at least one of, for example, a smart phone, a tablet Personal Computer (PC), a mobile phone, a video phone, an electronic book reader (e-book reader), a desktop PC, a laptop PC, a netbook computer, a workstation, a server, a Personal Digital Assistant (PDA), a Portable Multimedia Player (PMP), a MPEG-1 audio layer-3 (MP3) player, a mobile medical device, a camera, and a wearable device. According to various embodiments, the wearable device may include at least one of an accessory type (e.g., a watch, a ring, a bracelet, an anklet, a necklace, a glasses, a contact lens, or a Head-Mounted Device (HMD)), a fabric or clothing integrated type (e.g., an electronic clothing), a body-mounted type (e.g., a skin pad, or tattoo), and a bio-implantable type (e.g., an implantable circuit). In some embodiments, the electronic device may include at least one of, for example, a television, a Digital Video Disk (DVD) player, an audio, a refrigerator, an air conditioner, a vacuum cleaner, an oven, a microwave oven, a washing machine, an air cleaner, a set-top box, a home automation control panel, a security control panel, a TV box (e.g., Samsung HomeSync™, Apple TV™, or Google TV™), a game console (e.g., Xbox™ and PlayStation™), an electronic dictionary, an electronic key, a camcorder, and an electronic photo frame.

In other embodiments, the electronic device may include at least one of various medical devices (e.g., various portable medical measuring devices (a blood glucose monitoring device, a heart rate monitoring device, a blood pressure measuring device, a body temperature measuring device, etc.), a Magnetic Resonance Angiography (MRA), a Magnetic Resonance Imaging (MRI), a Computed Tomography (CT) machine, and an ultrasonic machine), a navigation device, a Global Positioning System (GPS) receiver, an Event Data Recorder (EDR), a Flight Data Recorder (FDR), a Vehicle Infotainment Devices, an electronic devices for a ship (e.g., a navigation device for a ship, and a gyro-compass), avionics, security devices, an automotive head unit, a robot for home or industry, an Automatic Teller's Machine (ATM) in banks, Point Of Sales (POS) in a shop, or internet device of things (e.g., a light bulb, various sensors, electric or gas meter, a sprinkler device, a fire alarm, a thermostat, a streetlamp, a toaster, a sporting goods, a hot water tank, a heater, a boiler, etc.). According to some embodiments, an electronic device may include at least one of a part of furniture or a building/structure, an electronic board, an electronic signature receiving device, a projector, and various types of measuring instruments (e.g., a water meter, an electric meter, a gas meter, a radio wave meter, and the like). In various embodiments, the electronic device may be flexible, or may be a combination of one or more of the aforementioned various devices. The electronic device according to one embodiment is not limited to the above described devices. In the present disclosure, the term “user” may indicate a person using an electronic device or a device (e.g., an artificial intelligence electronic device) using an electronic device.

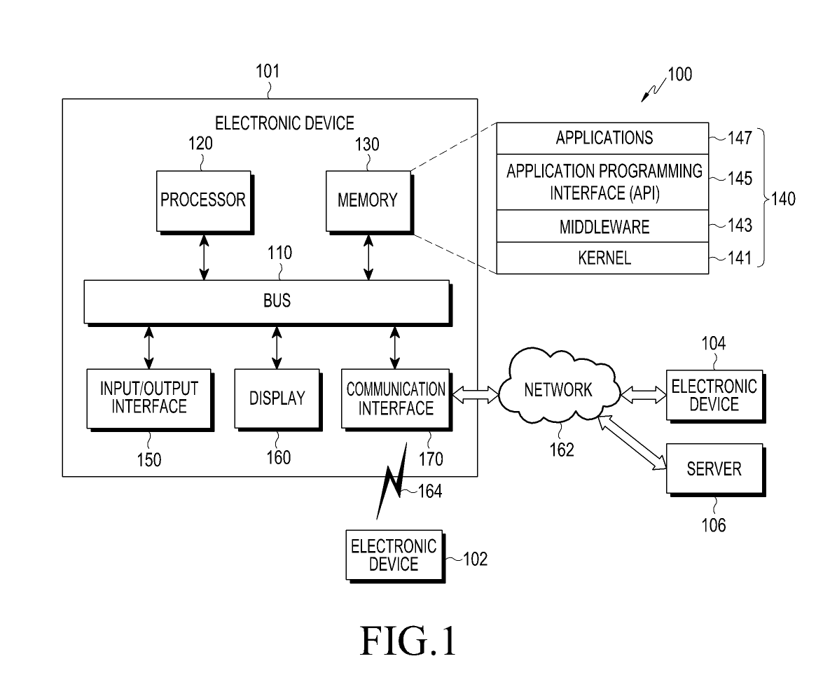

Referring to FIG. 1, an electronic device 101 within a network environment 100 according to various embodiments will be described. The electronic device 101 may include a bus 110, a processor 120, a memory 130, an input/output interface 150, a display 160, and a communication interface 170. In some embodiments, the electronic device 101 may omit at least one of the elements, or may further include other elements. The bus 110 may include a circuit that interconnects the elements 110 to 170 and transmits communication (e.g., control messages or data) between the elements. The processor 120 may include one or more of a central processing unit, an application processor, and a communication processor (CP). The processor 120, for example, may carry out operations or data processing relating to the control and/or communication of at least one other element of the electronic device 101.

The memory 130 may include a volatile and/or non-volatile memory. The memory 130 may store, for example, commands or data relevant to at least one other element of the electronic device 101. According to an embodiment, the memory 130 may store software and/or a program 140. The program 140 may include a kernel 141, middleware 143, an application programming interface (API) 145, and/or application programs (or “applications”) 147. At least some of the kernel 141, the middleware 143, and the API 145 may be referred to as an operating system. The kernel 141 may control or manage system resources (e.g., the bus 110, the processor 120, the memory 130, or the like) used for executing an operation or function implemented by other programs (e.g., the middleware 143, the API 145, or the application programs 147). Furthermore, the kernel 141 may provide an interface via which the middleware 143, the API 145, or the application programs 147 may access the individual elements of the electronic device 101 to control or manage the system resources.

The middleware 143 may function as, for example, an intermediary for allowing the API 145 or the application programs 147 to communicate with the kernel 141 to exchange data. Furthermore, the middleware 143 may process one or more task requests, which are received from the application programs 147, according to priorities thereof. For example, the middleware 143 may assign priorities to use the system resources (e.g., the bus 110, the processor 120, the memory 130, or the like) of the electronic device 101 to one or more of the application programs 147, and may process the one or more task requests. The API 145 is an interface via which the applications 147 control functions provided from the kernel 141 or the middleware 143, and may include, for example, at least one interface or function (e.g., instruction) for file control, window control, image processing, text control, or the like. For example, the input/output interface 150 may forward commands or data, input from a user or an external device, to the other element(s) of the electronic device 101, or may output commands or data, received from the other element(s) of the electronic device 101, to the user or the external device.

The display 160 may include, for example, a liquid crystal display (LCD), a light emitting diode (LED) display, an organic light emitting diode (OLED) display, a micro electro mechanical system (MEMS) display, or an electronic paper display. The display 160 may display, for example, various types of content (e.g., text, images, videos, icons, and/or symbols) for a user. The display 160 may include a touch screen, and may receive, for example, a touch input, a gesture input, a proximity input, or a hovering input using an electronic pen or the user's body part. The communication interface 170, for example, may set communication between the electronic device 101 and an external device (e.g., a first external electronic device 102 via wireless link 164 or any other suitable connection, a second external electronic device 104, or a server 106). For example, the communication interface 170 may be connected to a network 162 via wireless or wired communication to communicate with an external device (e.g., the second external electronic device 104 or the server 106).

The wireless communication may include, for example, a cellular communication that uses at least one of LTE, LTE-Advanced (LTE-A), code division multiple access (CDMA), wideband CDMA (WCDMA), universal mobile telecommunications system (UMTS), wireless broadband (WiBro), global system for mobile communications (GSM), or the like. According to an embodiment, the wireless communication may include, for example, at least one of Wi-Fi, Bluetooth, Bluetooth low energy (BLE), ZigBee, near field communication (NFC), magnetic secure transmission, radio frequency (RF), and body area network (BAN). According to an embodiment, the wired communication may include GNSS. The GNSS may be, for example, a global positioning system (GPS), a global navigation satellite system (Glonass), a Beidou navigation satellite system (hereinafter, referred to as “Beidou”), or Galileo (the European global satellite-based navigation system). Hereinafter, in this document, the term “GPS” may be interchangeable with the term “GNSS”. The wired communication may include, for example, at least one of a universal serial bus (USB), a high definition multimedia interface (HDMI), recommended standard 232 (RS-232), a plain old telephone service (POTS), and the like. The network 162 may include a telecommunications network, for example, at least one of a computer network (e.g., a LAN or a WAN), the Internet, and a telephone network.

Each of the first and second external electronic devices 102 and 104 may be of type that is the same as, or different from, the electronic device 101. According to various embodiments, all or some of the operations executed in the electronic device 101 may be executed in another electronic device or a plurality of electronic devices (e.g., the electronic devices 102 and 104 or the server 106). According to an embodiment, when the electronic device 101 has to perform some functions or services automatically or in response to a request, the electronic device 101 may make a request for performing at least some functions relating thereto to another device (e.g., the electronic device 102 and 104 or the server 106) instead of, or in addition to, performing the functions or services by itself. Another electronic device (e.g., the electronic device 102 and 104, or the server 106) may execute the requested functions or the additional functions, and may deliver a result of the execution to the electronic device 101. The electronic device 101 may provide the received result as it is, or may additionally process the received result to provide the requested functions or services. To this end, for example, cloud computing, distributed computing, or client-server computing technology may be used.

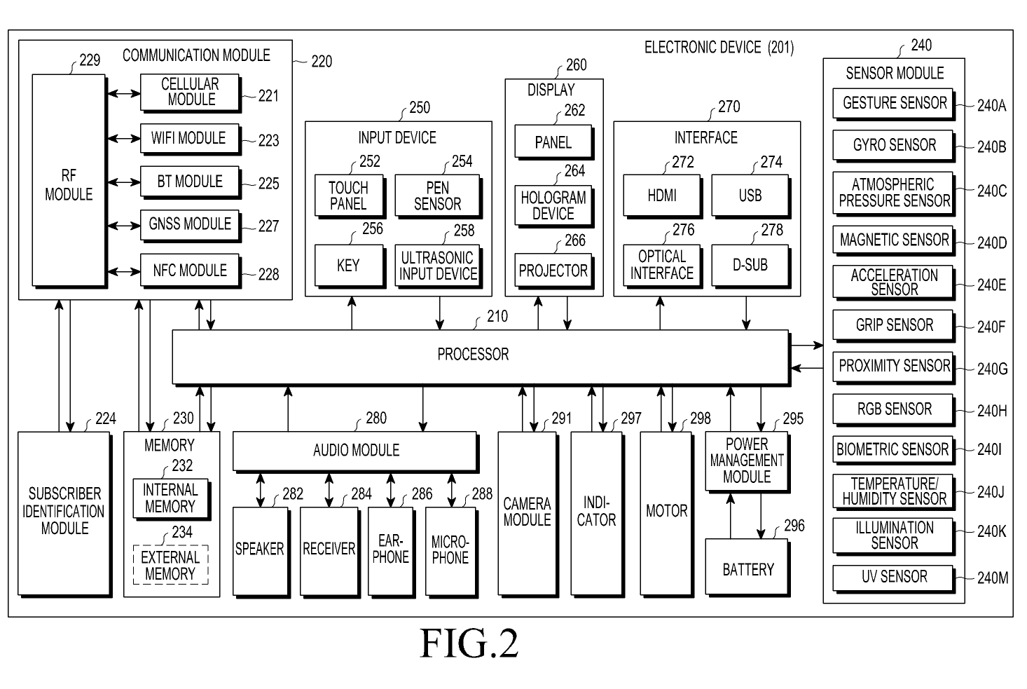

FIG. 2 is a block diagram of an electronic device according to various embodiments.

An electronic device 201 may include, for example, the whole or part of the electronic device 101 illustrated in FIG. 1. The electronic device 201 may include at least one processor 210 (e.g., an AP), a communication module 220, a subscriber identification module 224, a memory 230, a sensor module 240, an input device 250, a display 260, an interface 270, an audio module 280, a camera module 291, a power management module 295, a battery 296, an indicator 297, and a motor 298. The processor 210 may control a plurality of hardware or software elements connected thereto and may perform various data processing and operations by driving an operating system or an application program. The processor 210 may be implemented as, for example, a system on chip (SoC). According to an embodiment, the processor 210 may further include a graphic processing unit (GPU) and/or an image signal processor. The processor 210 may also include at least some of the elements illustrated in FIG. 2 (e.g., a cellular module 221). The processor 210 may load, in volatile memory, commands or data received from at least one of the other elements (e.g., non-volatile memory), may process the loaded commands or data, and store the resultant data in the non-volatile memory.

The communication module 220 may have a configuration that is the same as, or similar to, that of the communication interface 170. The communication module 220 may include, for example, a cellular module 221, a Wi-Fi module 223, a Bluetooth module 225, a GNSS module 227, an NFC module 228, and an RF module 229. The cellular module 221 may provide, for example, a voice call, a video call, a text message service, an Internet service, or the like via a communication network. According to an embodiment, the cellular module 221 may identify and authenticate the electronic device 201 within a communication network using the subscriber identification module 224 (e.g., a SIM card). According to an embodiment, the cellular module 221 may perform at least some of the functions that the processor 210 may provide. According to an embodiment, the cellular module 221 may include a communication processor (CP). According to some embodiments, at least some (e.g., two or more) of the cellular module 221, the Wi-Fi module 223, the Bluetooth module 225, the GNSS module 227, and the NFC module 228 may be included in one Integrated Chip (IC) or IC package. The RF module 229 may transmit/receive, for example, a communication signal (e.g., an RF signal). The RF module 229 may include, for example, a transceiver, a power amp module (PAM), a frequency filter, a low noise amplifier (LNA), an antenna, or the like. According to another embodiment, at least one of the cellular module 221, the Wi-Fi module 223, the Bluetooth module 225, the GNSS module 227, and the NFC module 228 may transmit/receive an RF signal via a separate RF module. The subscriber identification module 224 may include, for example, a card that includes a subscriber identity module and/or an embedded SIM, and may contain unique identification information (e.g., an integrated circuit card identifier (ICCID)) or subscriber information (e.g., an international mobile subscriber identity (IMSI)).

The memory 230 (e.g., the memory 130) may include, for example, an embedded memory 232 or an external memory 234. The embedded memory 232 may include, for example, at least one of volatile memory (e.g., a DRAM, an SRAM, an SDRAM, or the like) and non-volatile memory (e.g., a onetime programmable ROM (OTPROM), a PROM, an EPROM, an EEPROM, a mask ROM, a flash ROM, a flash memory, a hard disc drive, or a solid state drive (SSD)). The external memory 234 may include a flash drive, for example, a compact flash (CF), a secure digital (SD), a Micro-SD, a Mini-SD, an eXtreme digital (xD), a multi-media card (MMC), a memory stick, and the like. The external memory 234 may be functionally and/or physically connected to the electronic device 201 via various interfaces.

The sensor module 240 may, for example, measure a physical quantity or detect the operating state of the electronic device 201, and may convert the measured or detected information into an electrical signal. The sensor module 240 may include, for example, at least one of a gesture sensor 240A, a gyro sensor 240B, an atmospheric pressure sensor 240C, a magnetic sensor 240D, an acceleration sensor 240E, a grip sensor 240F, a proximity sensor 240G, a color sensor 240H (e.g., a red, green, blue (RGB) sensor), a biometric sensor 240I, a temperature/humidity sensor 240J, an illumination sensor 240K, and a ultraviolet (UV) sensor 240M. Additionally or alternatively, the sensor module 240 may include, for example, an e-nose sensor, an electromyography (EMG) sensor, an electroencephalogram (EEG) sensor, an electrocardiogram (ECG) sensor, an infrared (IR) sensor, an iris sensor, and/or a fingerprint sensor. The sensor module 240 may further include a control circuit for controlling one or more sensors included therein. In some embodiments, the electronic device 201 may further include a processor, which is configured to control the sensor module 240, as a part of the processor 210 or separately from the processor 210 in order to control the sensor module 240 while the processor 210 is in a sleep state.

The input device 250 may include, for example, a touch panel 252, a (digital) pen sensor 254, a key 256, or an ultrasonic input device 258. The touch panel 252 may use, for example, at least one of a capacitive type, a resistive type, an infrared type, and an ultrasonic type. Furthermore, the touch panel 252 may further include a control circuit. The touch panel 252 may further include a tactile layer to provide a tactile reaction to a user. The (digital) pen sensor 254 may include, for example, a recognition sheet that is a part of, or separate from, a touch panel. The key 256 may include, for example, a physical button, an optical key, or a keypad. The ultrasonic input device 258 may detect ultrasonic waves, which are generated by an input tool, via a microphone (e.g., a microphone 288) to identify data corresponding to the detected ultrasonic waves.

The display 260 (e.g., the display 160) may include a panel 262, a hologram device 264, a projector 266, and/or a control circuit for controlling them. The panel 262 may be implemented to be, for example, flexible, transparent, or wearable. The panel 262, together with the touch panel 252, may be configured as one or more modules. According to an embodiment, the panel 262 may include a pressure sensor (or a force sensor) which may measure the strength of pressure of a user's touch. The pressure sensor may be implemented so as to be integrated with the touch panel 252 or may be implemented as one or more sensors separate from the touch panel 252. The hologram device 264 may show a three dimensional image in the air by using light interference. The projector 266 may display an image by projecting light onto a screen. The screen may be located, for example, in the interior of, or on the exterior of, the electronic device 201. The interface 270 may include, for example, an HDMI 272, a USB 274, an optical interface 276, or a D-subminiature (D-sub) 278. The interface 270 may be included in, for example, the communication circuit 170 illustrated in FIG. 1. Additionally or alternatively, the interface 270 may, for example, include a mobile high-definition link (MHL) interface, a secure digital (SD) card/multi-media card (MMC) interface, or an infrared data association (IrDA) standard interface.

The audio module 280 may convert, for example, sound into an electrical signal, and vice versa. At least some elements of the audio module 280 may be included, for example, in the input/output interface 145 illustrated in FIG. 1. The audio module 280 may process sound information that is input or output via, for example, a speaker 282, a receiver 284, earphones 286, the microphone 288, or the like. The camera module 291 is a device that is capable of photographing a still image and a video. According to an embodiment, the camera module 291 may include one or more image sensors (e.g., a front sensor or a rear sensor), a lens, an image signal processor (ISP), or a flash (e.g., an LED or xenon lamp). The power management module 295 may manage, for example, the power of the electronic device 201. According to an embodiment, the power management module 295 may include a power management integrated circuit (PMIC), a charger IC, or a battery or fuel gauge. The PMIC may use a wired and/or wireless charging method. Examples of the wireless charging method may include a magnetic resonance method, a magnetic induction method, an electromagnetic wave method, and the like. Additional circuits (e.g., a coil loop, a resonance circuit, a rectifier, and the like) for wireless charging may be further included. The battery gauge may measure, for example, the amount of charge remaining in the battery 296, and a voltage, a current, or a temperature while charging. The battery 296 may include, for example, a rechargeable battery and/or a solar battery.

The indicator 297 may display a particular state, for example, a booting state, a message state, a charging state, or the like of the electronic device 201 or a part (e.g., the processor 210) of the electronic device 201. The motor 298 may convert an electric signal into a mechanical vibration, and may generate a vibration, a haptic effect, or the like. The electronic device 201 may include a mobile TV support device (e.g., a GPU) that is capable of processing media data according to a standard, such as digital multimedia broadcasting (DMB), digital video broadcasting (DVB), mediaFlo™, and the like. Each of the above-described elements described in the present disclosure may be configured with one or more components, and the names of the corresponding elements may vary based on the type of electronic device. In various embodiments, an electronic device (e.g., the electronic device 201) may omit some elements or may further include additional elements, or some of the elements of the electronic device may be combined with each other to configure one entity, and the entity may identically perform the functions of the corresponding elements prior to the combination.

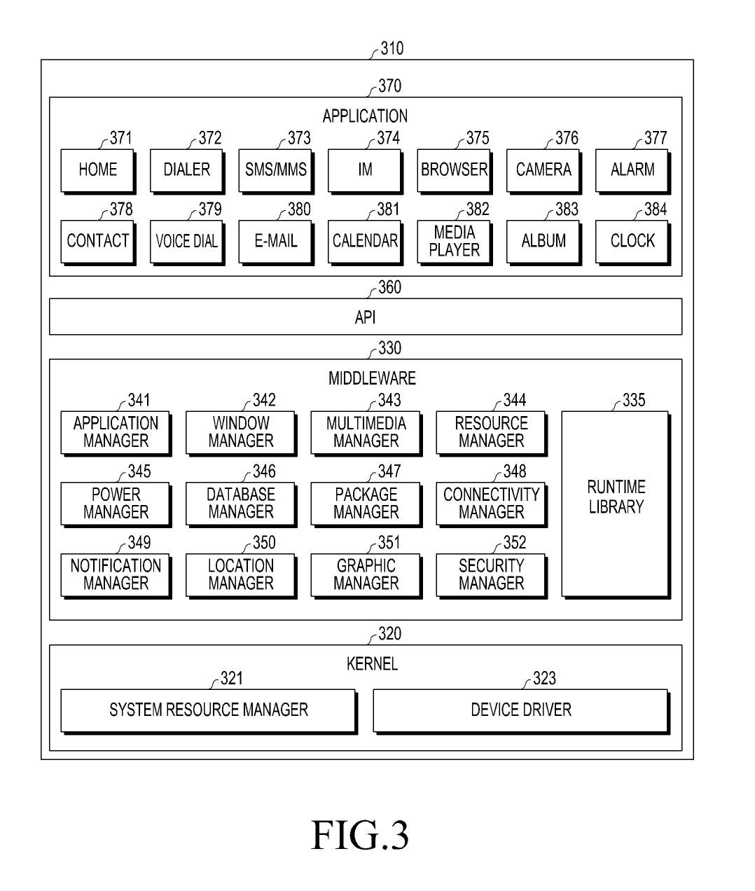

FIG. 3 is a block diagram of a program module according to various embodiments.

According to an embodiment, a program module 310 (e.g., the program 140) may include an operating system (OS) that controls resources relating to an electronic device (e.g., the electronic device 101) and/or various applications (e.g., the application programs 217) that are driven on the operating system. The operating system may include, for example, Android™, iOS™, Windows™, Symbian™, Tizen™, or Bada™. Referring to FIG. 3, the program module 310 may include a kernel 320 (e.g., the kernel 141), middleware 330 (e.g., the middleware 143), an API 360 (e.g., the API 145), and/or applications 370 (e.g., the application programs 147). At least a part of the program module 310 may be preloaded on the electronic device, or may be downloaded from an external electronic device (e.g., the electronic device 102 and 104 or the server 106).

The kernel 320 may include, for example, a system resource manager 321 and/or a device driver 323. The system resource manager 321 may control, allocate, or retrieve system resources. According to an embodiment, the system resource manager 321 may include a process manager, a memory manager, or a file system manager. The device driver 323 may include, for example, a display driver, a camera driver, a Bluetooth driver, a shared memory driver, a USB driver, a keypad driver, a Wi-Fi driver, an audio driver, or an inter-process communication (IPC) driver. The middleware 330 may provide, for example, a function required by the applications 370 in common, or may provide various functions to the applications 370 via the API 360 such that the applications 370 may efficiently use limited system resources within the electronic device. According to an embodiment, the middleware 330 may include at least one of a runtime library 335, an application manager 341, a window manager 342, a multi-media manager 343, a resource manager 344, a power manager 345, a database manager 346, a package manager 347, a connectivity manager 348, a notification manager 349, a location manager 350, a graphic manager 351, and a security manager 352.

The runtime library 335 may include, for example, a library module that a compiler uses in order to add a new function via a programming language while the applications 370 are being executed. The runtime library 335 may manage an input/output, manage a memory, or process an arithmetic function. The application manager 341 may manage, for example, the life cycles of the applications 370. The window manager 342 may manage GUI resources used for a screen. The multimedia manager 343 may identify formats required for reproducing media files and may encode or decode a media file using a codec suitable for a corresponding format. The resource manager 344 may manage the source code of the applications 370 or the space in memory. The power manager 345 may manage, for example, the capacity or power of a battery and may provide power information required for operating the electronic device. According to an embodiment, the power manager 345 may interoperate with a basic input/output system (BIOS). The database manager 346 may, for example, generate, search, or change databases to be used by the applications 370. The package manager 347 may manage the installation or update of an application that is distributed in the form of a package file.

The connectivity manager 348 may manage, for example, a wireless connection. The notification manager 349 may provide an event (e.g., an arrival message, an appointment, a proximity notification, and the like) to a user. The location manager 350 may manage, for example, the location information of the electronic device. The graphic manager 351 may manage a graphic effect to be provided to a user and a user interface relating to the graphic effect. The security manager 352 may provide, for example, system security or user authentication. According to an embodiment, the middleware 330 may include a telephony manager for managing a voice or video call function of the electronic device, or a middleware module that is capable of forming a combination of the functions of the above-described elements. According to an embodiment, the middleware 330 may provide modules specialized according to the types of operation systems. The middleware 330 may dynamically remove some of the existing elements, or may add new elements. The API 360 is, for example, a set of API programming functions, and may be provided in different configurations depending on the operating system. For example, in the case of Android or iOS, one API set may be provided for each platform, and in the case of Tizen, two or more API sets may be provided for each platform.

The applications 370 may include applications that provide, for example, a home 371, a dialer 372, a SMS/MMS 373, instant messaging (IM) 374, a browser 375, a camera 376, an alarm 377, contacts 378, a voice dialer 379, an e-mail 380, a calendar 381, a media player 382, an album 383, a watch 384, health care (e.g., measuring exercise quantity or blood glucose), environment information (e.g., atmospheric pressure, humidity, or temperature information), and the like. According to an embodiment, the applications 370 may include an information exchange application that is capable of supporting the exchange of information between the electronic device and an external electronic device. The information exchange application may include, for example, a notification relay application for relaying particular information to an external electronic device, or a device management application for managing an external electronic device. For example, the notification relay application may relay notification information generated in the other applications of the electronic device to an external electronic device, or may receive notification information from an external electronic device to provide the received notification information to a user. The device management application may install, delete, or update functions of an external electronic device that communicates with the electronic device (e.g., turning on/off the external electronic device itself (or some elements thereof) or adjusting the brightness (or resolution) of a display) or applications executed in the external electronic device. According to an embodiment, the applications 370 may include applications (e.g., a health care application of a mobile medical appliance) that are designated according to the attributes of an external electronic device. According to an embodiment, the applications 370 may include applications received from an external electronic device. At least some of the program module 310 may be implemented (e.g., executed) by software, firmware, hardware (e.g., the processor 210), or a combination of two or more thereof, and may include a module, a program, a routine, an instruction set, or a process for performing one or more functions.

According to various embodiments, an electronic device is provided, the electronic device including: a frequency determining unit configured to determine a delta frequency corresponding to a difference between a first frequency for RF communication and a second frequency output from a frequency synthesis unit; a digitally-controlled crystal oscillator (DCXO) configured to include a plurality of capacitors including a first variable capacitor and a second variable capacitor, and an oscillator connected to the plurality of capacitors and outputting a clock; and a processor configured to change capacitances of the first variable capacitor and the second variable capacitor by applying a first control value to the first variable capacitor and applying a second control value to the second variable capacitor, based on the delta frequency.

According to an embodiment, the first control value and the second control value are digital bits. The first control value is set to divide a predetermined compensation frequency range by predetermined bits, and to change a value of the first capacitor by a first capacitance every time the first control value increases by one bit. The second control value is set to divide the first control value by predetermined bits, and to change a value of the second capacitor by a second capacitance which is smaller than the first capacitance every time the second control value increases by one bit within the first control value.

According to an embodiment, at a point in time at which the first control value increases by one bit, the processor is configured to change a start bit of the second control value to a bit that is some bits higher than a start bit of the predetermined bits of the second control value.

According to an embodiment, the electronic device may further include a frequency synthesizer configured to output a reference frequency according to a clock of the oscillator.

According to an embodiment, at a point different from the point in time at which the first control value increases by one bit, the processor is configured to apply the start bit of the second control value as the start bit of the predetermined bits of the second control value.

According to various embodiments, an electronic device is provided, wherein the electronic device includes: a frequency synthesis unit configured to output a reference frequency required for RF transmission/reception modulation; an RF transceiving module configured to modulate/demodulate an RF transmission/reception signal; and a baseband module configured to convert data to be transmitted into a baseband signal, provide the baseband signal to the RF transceiving module, and convert a received RF signal into a baseband signal, wherein the RF transceiving module includes: a frequency determining unit configured to determine a delta frequency corresponding to a difference between a first frequency for RF communication and a second frequency output from the frequency synthesis unit; and a digitally-controlled crystal oscillator (DCXO) configured to include a plurality of capacitors including a first variable capacitor and a second variable capacitor, and an oscillator connected to the plurality of capacitors and outputting a clock, and the baseband module includes: a processor configured to change capacitances of the first variable capacitor and the second variable capacitor by applying a first control value to the first variable capacitor and applying a second control value to the second variable capacitor, based on the delta frequency.

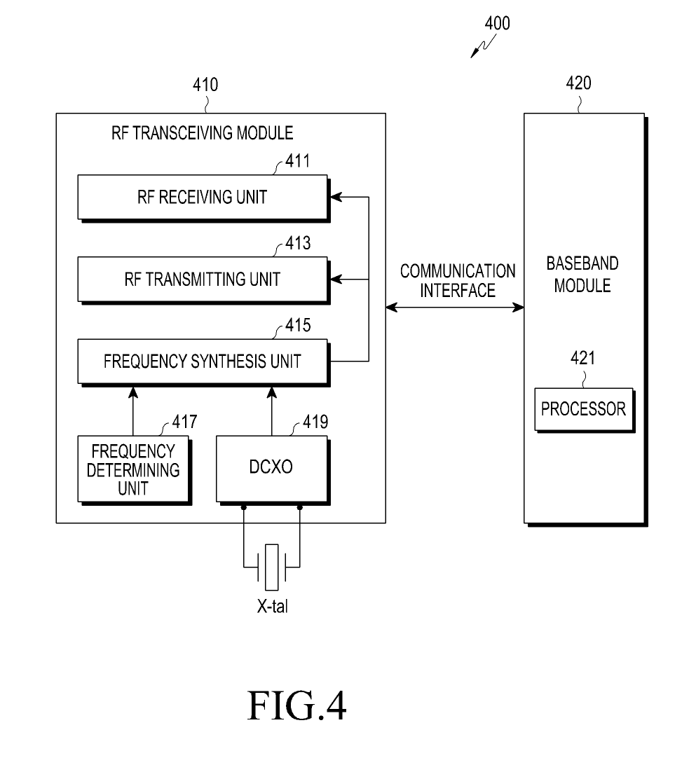

FIG. 4 is a block diagram illustrating a transceiving module and a baseband module in an electronic device according to various embodiments.

An electronic device 400 may include a radio frequency (RF) transceiving module 410 and a baseband module 420.

The RF transceiving module 410, including transceiving circuitry, may include an RF receiving unit 411, an RF transmitting unit 413, a frequency synthesis unit 415 which includes frequency synthesis circuitry, a frequency determining unit 417 including frequency determining circuitry, a digitally-controlled crystal oscillator (DCXO) 419.

The RF receiving unit 411 may receive an RF signal from the outside, such as a base station or the like, and may demodulate the received signal to a baseband signal. The RF transmitting unit 413 may modulate baseband signals to be transmitted, which are received from the baseband module 420, to RF signals.

The frequency synthesis unit 415 may synthesis and output a reference frequency to be used by each of the RF receiving unit 411 and the RF transmitting unit 413 for RF signal modulation/demodulation, according to a reference clock provided from the DCXO 419.

The frequency determining unit 417 may determine a frequency (hereinafter referred to as (delta frequency (df)) corresponding to a difference between the reference frequency to be output for RF signal modulation/demodulation and a frequency actually output by the frequency synthesis unit 415. The difference between the reference frequency output for RF signal modulation/demodulation and the frequency actually output by the frequency synthesis unit 415 may occur according to various factors. For example, from the perspective of an external factor of the electronic device, the difference between a reference frequency and a frequency actually output by the frequency synthesis unit 415 may occur according to propagation delay during signal transmission/reception from a base station. As another example, from the perspective of an internal factor of the electronic device, the difference between the reference frequency to be output for RF signal modulation/demodulation and the frequency actually output by the frequency synthesis unit 415 may occur when the frequency of a crystal oscillator changes as the temperature of the electronic device changes. Also, the difference between the reference frequency to be output for RF signal modulation/demodulation and the frequency actually output by the frequency synthesis unit 415 may occur due to various factors such as pressure, shaking, or the like, in addition to temperature.

The DCXO 419 may be connected to a crystal (X-tal), and may include a plurality of capacitors. The DCXO 419 may output a reference clock (hereinafter referred to as a ‘first reference clock’) corresponding to the reference frequency using X-tal. The DCXO 419 may correct the first reference clock by changing capacitance values of some of a plurality of capacitors according to a control signal associated with a delta frequency when the delta frequency occurs, and may output the corrected reference clock (hereinafter referred to as a ‘second reference clock’). According to various embodiments, the plurality of capacitors may at least include a first variable capacitor (CDAC) and a second variable capacitor (CAFC). The first variable capacitor (CDAC) may be a capacitor of which the capacitance value is changed by a first value according to a first control signal. The second variable capacitor (CAFC) may be a capacitor of which the capacitance value is changed by a second value, which is smaller than the first value, according to a second control signal. According to various embodiments, the DCXO 419 may correct the first reference clock by changing the capacitance value of at least one of the first variable capacitor (CDAC) and the second variable capacitor (CAFC) according to the control signal associated with the delta frequency, and may output the second reference clock. According to various embodiments, the RF transceiving module 410 may further include a register (not illustrated), and may change a register value according to the control signal associated with the delta frequency. The DCXO 419 may correct a reference clock by changing the capacitance values of some of a plurality of capacitors according to the changed register value via the register (not illustrated).

The baseband module 420 may convert data to be transmitted according to at least one radio communication protocol into baseband signals, and may convert received baseband signals into data. According to various embodiments, a radio communication protocol may be one of the 3^{rd} generation mobile communication related protocols, such as GSM, WCDMA, GPRS, or the like which are based on the discussion of international organizations such as GSMA, 3GPP, ITU, or the like, and the 4^{th} generation mobile communication-related protocols, such as Long Term Evolution (LTE), Long Term Evolution-Advanced (LTE-A), or the like, and the radio communication protocol may be another protocol related to radio communication, other than the above-described examples.

The baseband module 420 may output a control signal associated with a delta frequency to the DCXO 419 via the processor 421 according to the delta frequency determined by the frequency determining unit 417. The control signal associated with the delta frequency may be transmitted from the processor 421 to the DCXO 419 via a communication interface between the RF transceiving module 410 and the baseband module 420, or the control signal associated with the delta frequency may be registered in a register (not illustrated) and may be recognized by the DCXO 419. According to various embodiments, the processor 421 may be included in the RF transceiving module 410, as opposed to the baseband module 420, and may be included in the electronic device 400 as a separate module. According to various embodiments, the processor 421 may determine a CDAC value and an AFCDAC value which respectively correspond to control values for the first variable capacitor (CDAC) and the second variable capacitor (CAFC), according to a delta frequency determined by the frequency determining unit 417. According to various embodiments, the CDAC value and the AFCDAC value may be digital values. According to various embodiments, the CDAC value may be a first variable capacitor (CDAC) compensation value for compensating for a delta frequency, and the AFCDAC value may be a second variable capacitor (CAFC) compensation value for compensating for the delta frequency. According to an embodiment, the CDAC value may be a digital value set to increase a frequency by several kHz as the CDAC value increases by one bit. The AFCDAC value may be a digital value set to increase a frequency by several Hz as the AFCDAC value increases by one bit.

According to various embodiments, compensation for a several-kHz frequency may be performed via the CDAC value. A control signal for the compensation for a several-Hz frequency may be output via the AFCDAC value. Via the combination of the CDAC value and the AFCDAC value, a control signal for compensating for a delta frequency of Hz to kHz may be output.

According to an embodiment, in the case in which the CDAC value and the AFCDAC value are digital values, and the capacitor values of the first variable capacitor (CDAC) and the second variable capacitor (CAFC) are analog values, when the CDAC value and the AFCDAC value are changed, the capacitor values of the first variable capacitor (CDAC) and the second variable capacitor (CAFC) may not be changed linearly according to the changes of the CDAC value and the AFCDAC value.

As described above, when the capacitor values of the first variable capacitor (CDAC) and the second variable capacitor (CAFC), which are controllable based on the CDAC value and the AFCDAC value, are not linear, the frequency compensation values associated with the CDAC value and the AFCDAC value may not be linear. Also, a variation in the capacitance of the first variable capacitor (CDAC) made as the CDAC value increases by one bit is larger than a variation in the capacitance of the second variable capacitor (CAFC) made as the AFCDAC value increases by one bit, and thus, the nonlinearity of the CDAC value is more noticeable than the nonlinearity of the AFCDAC value. According to an embodiment, it is identified that a section where some frequency compensation values overlap when the CDAC value is changed is remarkably shown in a graph showing a slope of frequency compensation values associated with the CDAC value and the AFCDAC value.

According to an embodiment, the processor 421 may determine whether the current section is a section where frequency compensation values overlap due to a change of the CDAC value, using a result of determination of the CDAC value and the AFCDAC value.

The processor 421 may output a control signal associated with a delta frequency using the determined CDAC value and the AFCDAC value, when the current section is not a section where frequency compensation values overlap. When the current section is a section where frequency compensation values overlap, the processor 421 may change the AFCDAC value so as to remove the frequency compensation overlap, and may output a control signal associated with a delta frequency using the determined CDAC value and the changed AFCDAC value.

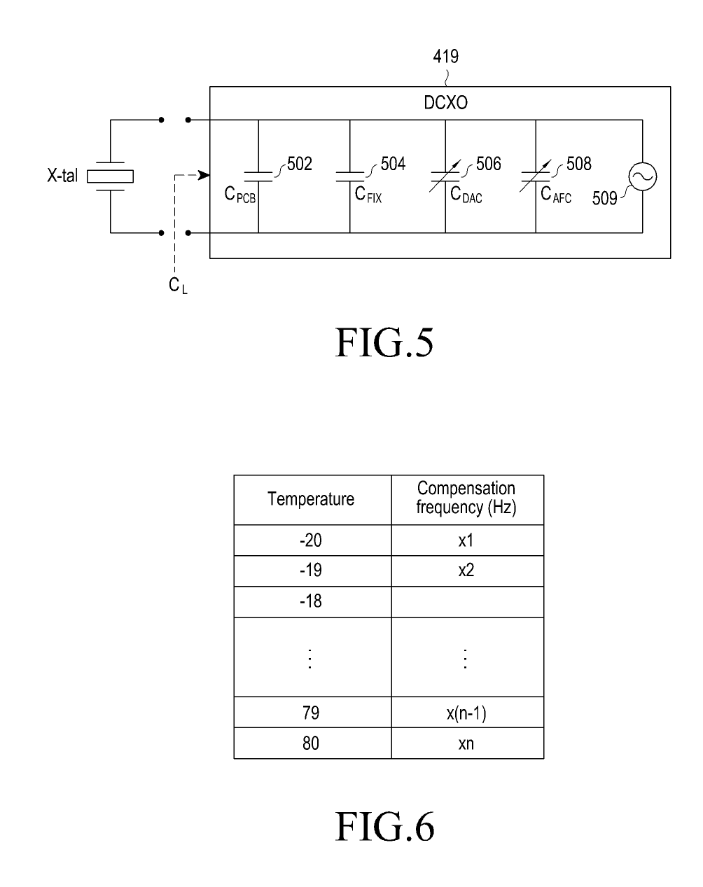

FIG. 5 is a conceptual diagram illustrating a circuit of a DCXO according to various embodiments.

Referring to FIG. 5, the DCXO 419 may be connected to a crystal (X-tal), and may include a plurality of capacitors 502, 504, 506, and 508 and an oscillator 509. The crystal (X-tal) is an oscillator, which oscillates by an oscillation circuit and generates an oscillation frequency. The oscillator 509 may generate a reference clock according to the oscillation frequency and the values of the plurality of capacitors 502, 504, 506, and 508. The plurality of capacitors 502, 504, 506, and 508 may include the CPCB 502, the CFIX 504, the CDAC 506, and the CAFC 508.

The CPCB 502 may be a capacitor of a printed circuit board (PCB) in which DCXO 419 is integrated. The CFIX 504 may be a capacitor fixed to the DCXO 419. The CDAC 506 may be a first variable capacitor. The CAFC 508 may be a second variable capacitor. The first variable capacitor (CDAC) may be a capacitor of which the capacitance value is changed by a first value according to a first control signal. The second variable capacitor (CAFC) may be a capacitor of which the capacitance value is changed by a second value, which is smaller than the first value, according to a second control signal. The oscillation frequency may be controlled according to the total sum (CL) of the capacitance values of the plurality of capacitors, whereby a reference clock may be controlled. The oscillator 509 may output a controlled reference clock. According to various embodiments, the capacitance of at least one of the first variable capacitor (CDAC) and the second variable capacitor (CAFC) may be changed based on a control signal associated with a delta frequency.

According to various embodiments, the delta frequency is a difference between a reference frequency to be output for RF signal modulation/demodulation and a frequency actually output by the frequency synthesis unit 415. The delta frequency may be attributable to propagation delay when signal transmission and reception is performed by a base station from the perspective of an external factor of an electronic device, or may be attributable to a change in the frequency of a crystal oscillator as the temperature of the electronic device changes from the perspective of an internal factor of the electronic device. Furthermore, the delta frequency may occur due to various factors such as pressure, shaking, or the like, other than temperature.

FIG. 6 is a diagram illustrating a temperature compensation table according to various embodiments.

Referring to FIG. 6, the capacitance of a variable capacitor related to temperature compensation may be controlled using a compensation frequency value associated with a temperature change according to a predetermined temperature compensation table.

According to an embodiment, when the temperature is −20° C. and a compensation frequency is x1 Hz, a reference clock may be corrected by changing the capacitance of a variable capacitor related to temperature compensation by x1 Hz that corresponds to the compensation frequency, whereby a reference frequency corrected according to the corrected reference clock may be output. However, according to the above-described method, a frequency control range (dynamic range of AFC) may be limited to the range in which controlling the variable capacitor related to the temperature compensation is allowed.

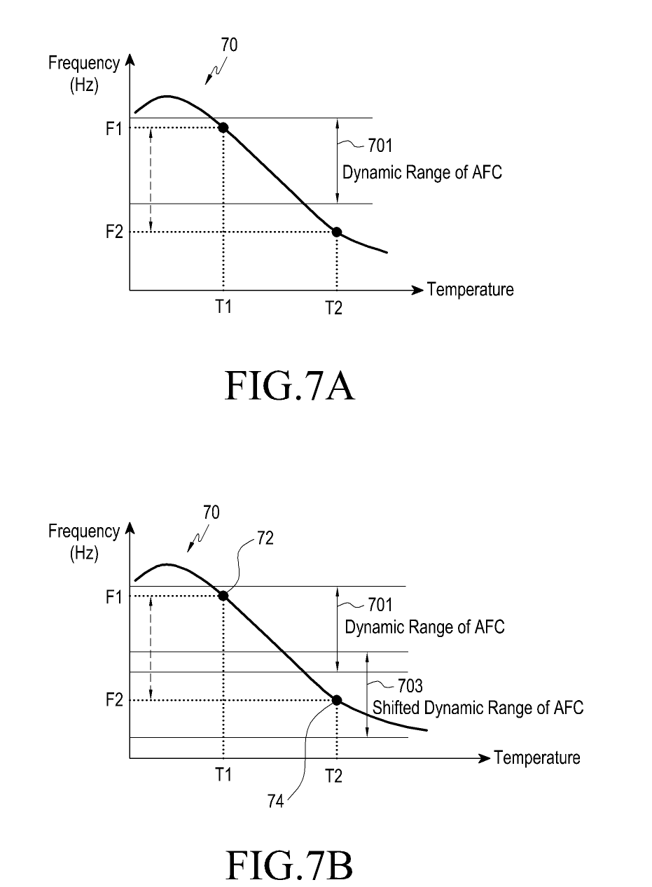

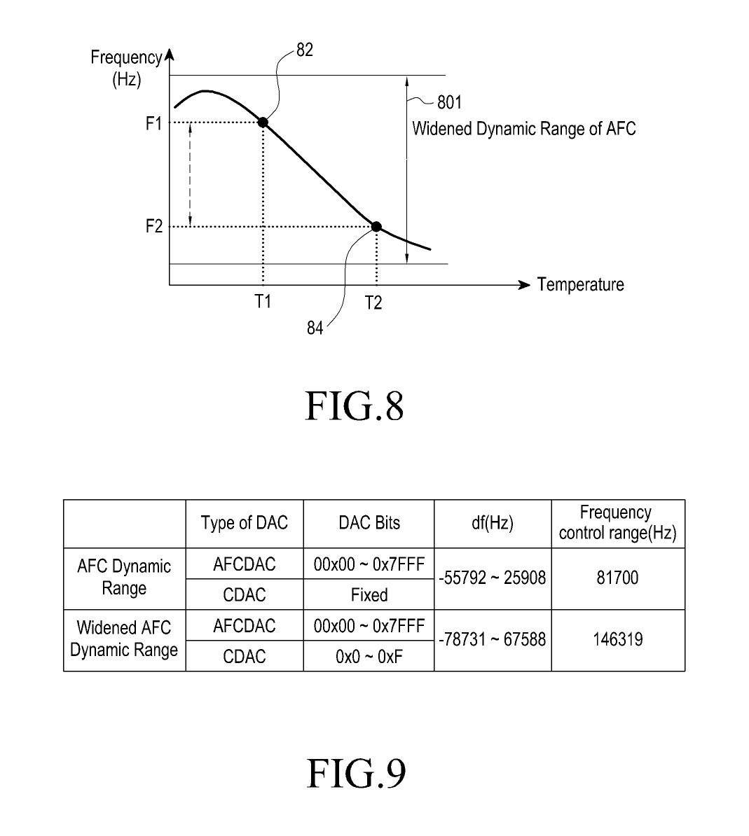

FIGS. 7A, 7B, and 8 are graphs illustrating a change in a frequency as a temperature changes according to various embodiments.

FIG. 7A shows a graph of the case in which a compensation frequency value associated with a temperature change according to a previously designated temperature compensation table is controlled using the capacitance of a variable capacitor related to temperature compensation.

Diagram 70 is a compensation frequency change curve associated with a temperature. Diagram 701 may be a predetermined frequency control range (dynamic range of AFC). The predetermined frequency control range may be a capacitance control range of a variable capacitor related to temperature compensation. The X-axis indicates a temperature, and the Y-axis indicates a frequency that needs to be compensated. The temperature when frequency compensation start is T1, and the temperature when a predetermined period of time elapses is T2, the frequency variation may be (F1-F2). When (F1-F2) is greater than the predetermined frequency control range (dynamic range of AFC) 701, the frequency compensation based on temperature change may not be performed.

According to another embodiment, in addition to the temperature compensation table, a separate temperature compensation algorithm may be applied, whereby the frequency compensation may be performed although (F1-F2) is greater than the predetermined frequency control range (dynamic range of AFC) 701.

Referring to FIG. 7B, the predetermined frequency control range (dynamic range of AFC) 701 may be shifted (moved) according to the temperature compensation algorithm. Although (F1-F2) is greater than the predetermined frequency control range (dynamic range of AFC) 701, frequency compensation based on a temperature change may be performed by shifting the frequency control range (dynamic range of AFC) 701 from F1 72 to F2 74 according to the temperature compensation algorithm.

The method of using the temperature compensation table or the method of using the temperature compensation table and the temperature compensation algorithm together are methods of controlling a variable capacitor for frequency compensation based on a temperature change, wherein the frequency control range may be limited to a predetermined range (dynamic range of AFC). Also, the method of using the temperature compensation table or the method of using the temperature compensation table and the temperature compensation algorithm together separately require a hardware element for measuring a temperature and software for executing a temperature-based frequency compensation algorithm, whereby the manufacturing cost of an electronic device increases and simplification of the structure of hardware and software of the electronic device may be difficult.

According to various embodiments, the control range of variable capacitors is extended such that a frequency control range becomes wider (widened dynamic range of AFC) than a variation of output frequencies of the frequency synthesis unit 415 attributable to a temperature change, a reference frequency is corrected by tracking a delta frequency that needs to be compensated for, and all of the first variable capacitor (CDAC) and the second variable capacitor (CAFC) may be used as variable capacitors related to temperature compensation, instead of determining one variable capacitor related to temperature compensation, whereby a widened frequency control range (widened dynamic range of AFC) has an actually wider frequency correction range, and frequency correction may be performed based on a temperature change.

Referring to FIG. 8, for a widened frequency control range (widened dynamic range of AFC) which is wider than before, the variation ranges of a CDAC value and an AFCDAC value may be determined in advance. In the case of the widened frequency control range (widened dynamic range of AFC), although a frequency change based on a temperature, for example, the range of F1 82 to F2 84, is greater than the existing frequency control range (dynamic range of AFC), the frequency correction based on a temperature change may be performed since the wider frequency control range (widened dynamic range of AFC) exists.

FIG. 9 is a diagram illustrating a table that compares DAC values between an existing frequency control range (dynamic range of AFC) and a widened frequency control range (widened dynamic range of AFC) according to various embodiments.

Referring to FIG. 9, an AFCDAC may be a control value for varying the capacitance of a first capacitor (e.g., the CAFC 508). A CDAC may be a control value for varying the capacitance of a second capacitor (e.g., the CDAC 506).

According to the existing frequency control range (dynamic range of AFC), based on a target frequency, the CDAC value may be fixed and the variation range of the AFCDAC value may be determined as a DAC value range predetermined based on the analog capacitance value of the CAFC 508.

According to the widened frequency compensation range (widened dynamic range of AFC), based on the target frequency, the variation ranges of the CDAC value and the AFCDAC value are determined, respectively, whereby the frequency control range may be widened when compared to when the CDAC value is fixed.

According to an embodiment, it is assumed that the CDAC value may vary within a four-bit value and the AFCDAC value may vary within a 15-bit value. In the existing frequency control range (dynamic range of AFC), according to the variation range of the AFCDAC value (00x00˜0x7FFF), a delta frequency section, which may be compensated for based on the target frequency, is −55792 Hz˜25908 Hz, and the frequency compensation range is 81700 Hz. According to an embodiment, in the widened frequency compensation range (widened dynamic range of AFC), according to the variation range of the CDAC value (0x00˜0x7FF) and the variation of the AFCDAC value (00x00˜0x7FFF), the delta frequency section, which may be compensated for based on the target frequency, is −78731 Hz˜67588 Hz, and the frequency compensation range is 146319 Hz.

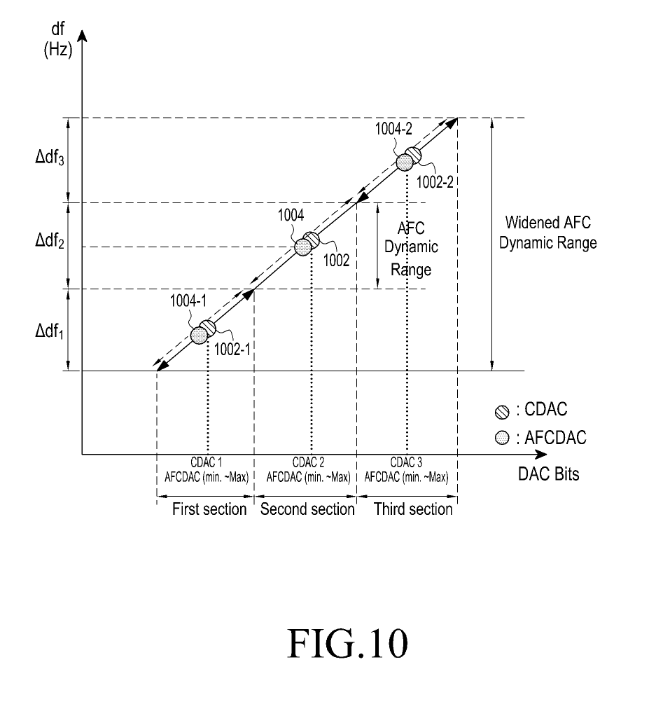

FIG. 10 is a graph illustrating the relationship between a CDAC, an AFCDAC, and a delta frequency according to various embodiments.

Referring to FIG. 10, the horizontal axis indicates a DAC value, and the vertical axis indicates a delta frequency (df). In the existing frequency control range (dynamic range of AFC), frequency correction may be performed by controlling an AFCDAC value 1004 within the frequency control range (AFC dynamic range) in the state in which a CDAC value 1002 is fixed. In the widened frequency control range (widened AFC dynamic range) according to various embodiments, a CDAC value may be controlled as opposed to being fixed, and frequency may be corrected by controlling an AFCDAC value within each controlled CDAC value section. According to an embodiment, the CDAC value 1002 may be controlled from 0x02 bits to a CDAC value 1002-1 of 0x01 bits, or may be controlled to a CDAC value 1002-2 of 0x03 bits. In a first section corresponding to 0x01 bits, the frequency may be corrected by Δdf1 according to control of the AFCDAC value 1004-1. In a second section corresponding to 0x02 bits, the frequency may be corrected by Δdf2 according to control of the AFCDAC value 1004. In a third section corresponding to 0x03 bits, the frequency may be corrected by Δdf3 according to control of the AFCDAC value 1004-2.

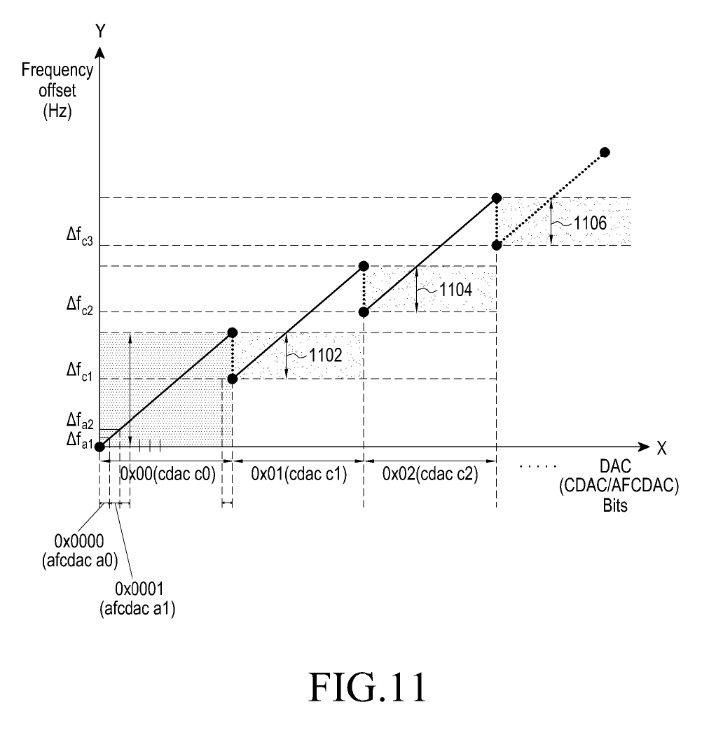

FIG. 11 is a graph illustrating the relationship between a CDAC value, an AFCDAC value, and a compensation frequency in an electronic device according to various embodiments.

Referring to FIG. 11, the X-axis indicates a DAC value, and the Y-axis indicates a frequency offset (hereinafter referred to a ‘compensation frequency’). The DAC value may include CDAC values and AFCDAC values.

The CDAC values correspond to compensation frequencies of several kHz, and the AFCDAC values correspond to compensation frequencies of several Hz. The DCXO 419 may compensate for a frequency of several Hz to kHz via the combination of a CDAC value and an AFCDAC value. According to an embodiment, when the CDAC value is 0x00(cdac c0), and the AFCDAC value is 0x0000(afcdac a0), a compensation frequency may be 0. When the CDAC value is 0x00(cdac c0) and the AFCDAC value is 0x0001(afcdac a1 1), a compensation frequency may be Δfa1. Also, when the CDAC value is 0x01(cdac c1), and the AFCDAC value is 0x0000(afcdac a0), a compensation frequency may be Δfc1. When the CDAC value is 0x01(cdac c1) and the AFCDAC value is 0x0001(afcdac a1 1), a compensation frequency may be Δfc1+Δfa1.

In the case in which the capacitor values of the first variable capacitor (CDAC) and the second variable capacitor (CAFC) are controlled using the CDAC value and the AFCDAC value, since the CDAC value and the AFCDAC value are digital values and the capacitor values of the first variable capacitor (CDAC) and the second variable capacitor (CAFC) are analog values, when the CDAC value and the AFCDAC value are changed, the capacitor values of the first variable capacitor (CDAC) and the second variable capacitor (CAFC) may not be changed linearly according to the changes of the CDAC value and the AFCDAC value. As described above, since the capacitor values of the first variable capacitor (CDAC) and the second variable capacitor (CAFC), which are controllable based on the CDAC value and the AFCDAC value, are not linear, the frequency compensation values associated with the CDAC value and the AFCDAC value may not be linear. Also, in the case of the CDAC value from among the CDAC value and the AFCDAC value, a variation in the capacitance value of the first variable capacitor (CDAC) made as the CDAC value increases by 1 is greater than a variation in the capacitance value of second variable capacitor (CAFC) made as the AFCDAC value increases by 1, whereby the nonlinearity of the CDAC value may be more remarkable than that of the AFCDAC value. Accordingly, as illustrated in FIG. 11, it is identified that sections 1102, 1104, and 1106 where some compensation frequency values overlap when the CDAC value is changed are remarkably shown in a graph showing a slope of frequency compensation values associated with the CDAC value and the AFCDAC value. Therefore, when the sections 1102, 1104, and 1106 where compensation frequency values overlap are removed, the frequency compensation values associated with the CDAC value and the AFCDAC value may become linear according to the CDAC value and the AFCDAC value.

According to various embodiments, a method of controlling a digitally-controlled crystal oscillator (DCXO) by an electronic device is provided, wherein the method includes: determining a delta frequency corresponding to a difference between a first frequency for RF communication and a second frequency output from a frequency synthesis unit; and changing capacitances of a first variable capacitor and a second variable capacitor by applying a first control value to the first variable capacitor and applying a second control value to the second variable capacitor, based on the delta frequency.

According to an embodiment, the first control value and the second control value are digital bits. The first control value is set to divide a predetermined compensation frequency range by predetermined bits, and to change a value of the first capacitor by a first capacitance every time the first control value increases by one bit. The second control value is set to divide the first control value by predetermined bits, and to change a value of the second capacitor by a second capacitance which is smaller than the first capacitance every time the second control value increases by one bit within the first control value.

According to an embodiment, the method may further include changing a start bit of the second control value to a bit that is specified bits higher than a start bit of the predetermined bits of the second control value at a point in time at which the first control value increases by one bit.

According to an embodiment, the method may further include outputting a reference frequency according the changed capacitances of the first variable capacitor and the second variable capacitor.

According to an embodiment, the method may further include applying the start bit of the second control value as the start bit of the predetermined bits of the second control value at a point different from the point in time at which the first control value increases by one bit.

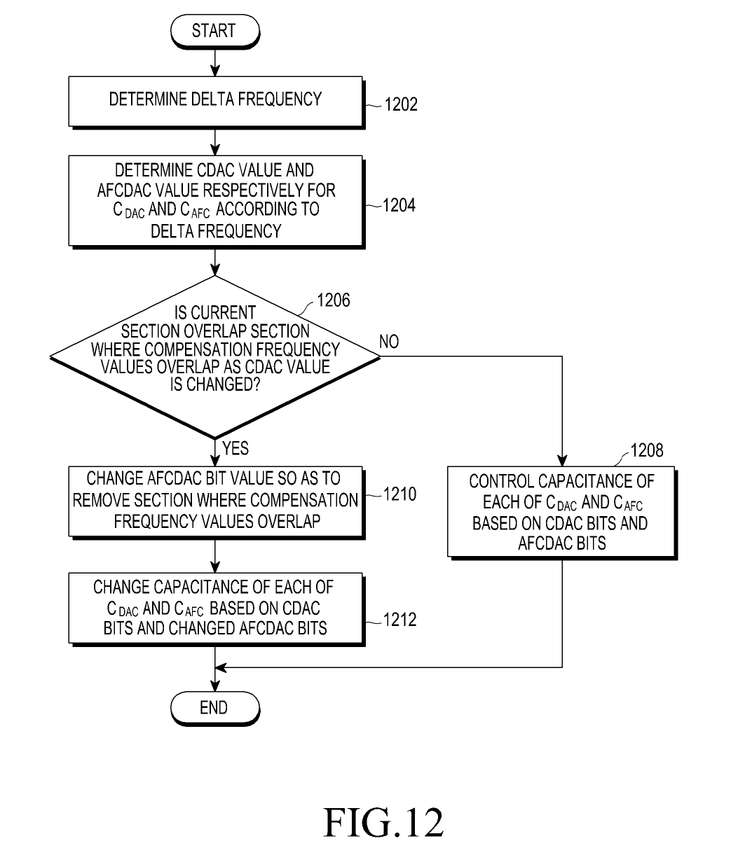

FIG. 12 is a diagram illustrating an operation of controlling a DCXO by an electronic device according to various embodiments.

Referring to FIG. 12, the electronic device determines a delta frequency in operation 1202. According to various embodiments, the electronic device may determine, using the frequency determining unit 417, a delta frequency corresponding to a difference between a first frequency to be output for RF signal modulation/demodulation and a second frequency actually output by the frequency synthesis unit 415. The difference between the first frequency to be output for RF signal modulation/demodulation and the second frequency actually output by the frequency synthesis unit 415 may occur according to various factors. For example, from the perspective of an external factor of the electronic device, the difference between a reference frequency and a frequency actually output by the frequency synthesis unit 415 may occur according to propagation delay during signal transmission/reception performed by base station. As another example, from the perspective of an internal factor of the electronic device, the difference between a reference frequency to be output for RF signal modulation/demodulation and a frequency actually output by the frequency synthesis unit 415 may occur when the frequency of a crystal oscillator changes as the temperature of the electronic device changes. Also, the difference between the reference frequency to be output by RF signal modulation/demodulation and the frequency actually output by the frequency synthesis unit 415 may occur due to various factors such as pressure, shaking, or the like, in addition to temperature.

The electronic device may determine a first control value (CDAC value) and a second control value (AFCDAC value) for controlling the capacitance of each of a first variable capacitor (CDAC) and a second variable capacitor (CAFC), according to the delta frequency, in operation 1204. The first variable capacitor (CDAC) may be a capacitor of which the capacitance value is changed by a first value according to a first control signal of the first control value. The second variable capacitor (CAFC) may be a capacitor of which the capacitance value is changed by a second value, which is smaller than the first value, according to a second control signal of the second control value.

According to various embodiments, the CDAC value and the AFCDAC value may be digital values. According to various embodiments, the CDAC value may be a first variable capacitor (CDAC) control value for compensating for the delta frequency, and the AFCDAC value may be a second variable capacitor (CAFC) control value for compensating for the delta frequency. According to an embodiment, the CDAC value may be a digital value set to increase a frequency by several kHz as the CDAC value increases by 1. The AFCDAC value may be a digital value set to increase a frequency by several Hz as the AFCDAC value increases by 1.

According to various embodiments, compensation for a several-kHz frequency may be performed via the CDAC value. A control signal for the compensation for a several-Hz frequency may be output via the AFCDAC value. Also, the electronic device may output a control signal for compensating for a delta frequency of several Hz to several kHz via the combination of the CDAC value and the AFCDAC value.

According to various embodiments, the CDAC values correspond to compensation frequencies of several kHz, and the AFCDAC values correspond to compensation frequencies of several Hz. The DCXO 419 may compensate for a frequency of several Hz to kHz, via the combination of the CDAC value and the AFCDAC value. For example, when the CDAC value is 0X00(cdac c0), a compensation frequency may be 0. When the CDAC value is 0X01(cdac c1), a compensation frequency may be Δfc1. When the CDAC value is 0X02(cdac c2), the compensation frequency may be Δfc2. Also, when the AFCDAC value is 0X00(afcdac 0), a compensation frequency may be 0. When the AFCDAC value is 0X01(afcdac 1), a compensation frequency may be Δfa1. When the AFCDAC value is 0X02(afcdac 2), a compensation frequency may be Δfa2.

In the case in which the capacitor values of the first variable capacitor (CDAC) and the second variable capacitor (CAFC) are controlled using the CDAC value and the AFCDAC value, since the CDAC value and the AFCDAC value are digital values and the capacitances of the first variable capacitor (CDAC) and the second variable capacitor (CAFC) are analog values, when the CDAC value and the AFCDAC value are changed, the capacitance of each of the first variable capacitor (CDAC) and the second variable capacitor (CAFC) may not be changed linearly according to the changes of the CDAC value and the AFCDAC value. As described above, since the capacitances of the first variable capacitor (CDAC) and the second variable capacitor (CAFC), which are controllable based on the CDAC value and the AFCDAC value, are not linear, the frequency compensation values associated with the CDAC value and the AFCDAC value may not be linear. Also, in the case of the CDAC value from among the CDAC value and the AFCDAC value, the variation in the capacitance value of the first variable capacitor (CDAC) made as the CDAC value increases by 1 is higher than the variation in the capacitance value of each second variable capacitor (CAFC) made as the AFCDAC value increases by 1, whereby the nonlinearity of the CDAC value may be more remarkable than that of the AFCDAC value. Accordingly, when the CDAC value is changed, a section where some compensation frequency values overlap may occur.

In operation 1206, the electronic device may determine whether the current section is a section where compensation frequency values overlap as the CDAC value is changed, based on a result of the determination of the CDAC value and the AFCDAC value.

When the current section is not the section where the compensation frequency values overlap as the CDAC value is changed, the electronic device may control the capacitance of each of the first variable capacitor (CDAC) and the second variable capacitor (CAFC) using the determined CDAC value and AFCDAC value in operation 1208. According to an embodiment, the processor 421 may output a control signal associated with the delta frequency using the determined CDAC value and AFCDAC value, and the DCXO 419 may change capacitance of each of the first variable capacitor (CDAC) and the second variable capacitor (CAFC) according to the control signal associated with the delta frequency.

When the current section is the section where the compensation frequency values overlap as the CDAC value is changed, the electronic device may change the determined AFCDAC value to an AFCDAC value that may remove the section where the compensation frequency values overlap, in operation 1210.

The electronic device may control the capacitance of each of the first variable capacitor (CDAC) and the second variable capacitor (CAFC) using the determined CDAC value and the changed AFCDAC value, in operation 1212. According to an embodiment, the processor 421 may output a control signal associated with a delta frequency using the determined CDAC value and the changed AFCDAC value, and the DCXO 419 may change the capacitance of each of the first variable capacitor (CDAC) and the second variable capacitor (CAFC) using the determined CDAC value and the changed AFCDAC value.

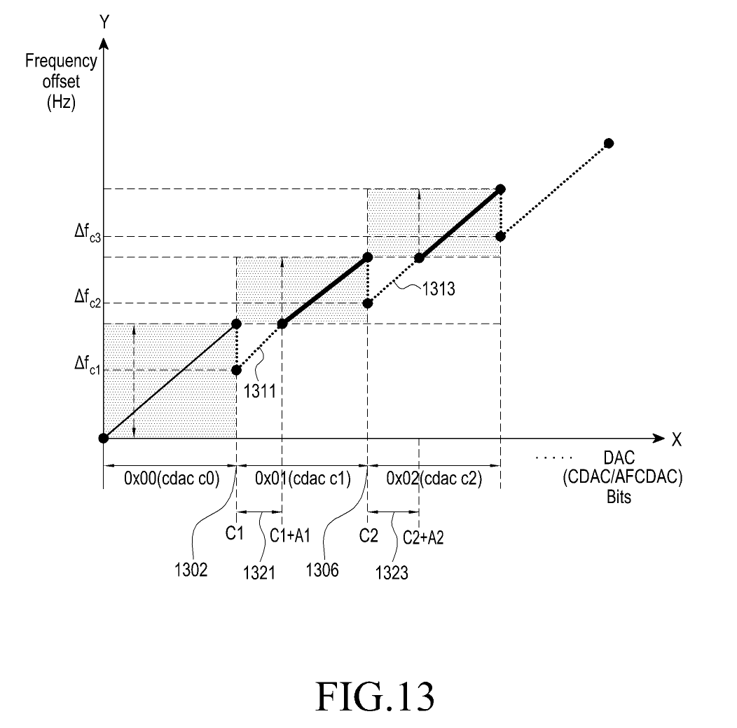

FIG. 13 is a graph illustrating a section where compensation frequency values overlap as a CDAC value is changed in an electronic device according to various embodiments.

Referring to FIG. 13, the X-axis indicates a DAC value, and the Y-axis indicates a frequency offset. The DAC value may include CDAC values and AFCDAC values. At a point in time 1302 and 1306 at which the CDAC value is changed, an overlap 1311 and 1313 of some compensation frequency values may be remarkably shown, and an electronic device may remove the section 1311 and 1313 where compensation frequency values overlap so that frequency compensation based on the CDAC value and the AFCDAC value may become linear.

According to various embodiments, the electronic device may enable an AFCDAC bit value to vary from the least significant bit (LSB) to the most significant bit (MSB) within a CDAC bit section. In order to remove a section where compensation frequency values overlap when a CDAC bit value is changed, the electronic device may enable the AFCDAC bit value to vary from a bit excluding the overlap section, as opposed to the LSB, to the MSB.

According to an embodiment, the electronic device may enable the AFCDAC value to vary from the LSB to the MSB in a first section (0x00(cdac c0)). In a second section (0x01(cdac c1)), the electronic device may disregard a first overlap section 1321 where compensation frequency values overlap among the entire section of the AFCDAC value in the second section, and may apply the AFCDAC value from a point (C1+A1) after the first overlap section. In a third section (0x02(cdac c2)) of the CDAC value, the electronic device may disregard a second overlap section 1323 where compensation frequency values overlap among the entire section of the AFCDAC value in the third section, and may apply the AFCDAC value from a point (C2+A2) after the second overlap section. In the same manner, the AFCDAC value may be applied until the CDAC value reaches MSB C(n).

According to various embodiments, when it is assumed that the AFCDAC values that start from respective sections of the CDAC value are A0, A1, A2, . . . , and A(N), respectively, a first AFCDAC value that starts from a first section of the CDAC value may be A0, an AFCDAC value that starts from a second section of the CDAC value may be A1, and an AFCDAC value that starts from an N^{th} section of the CDAC value may be A(N).

According to an embodiment, when it is assumed that the AFCDAC value is 16 bits, the first AFCDAC value that starts from the first section of the CDAC value may be 0x0000. When the second AFCDAC value that starts from the second section of the CDAC value is 0x0000, an overlap section may appear and thus, to prevent the overlap section, A1 which is the second AFCDAC value may take a start value that removes an overlap section, for example, 0x012C. Also, A2 which is the third AFCDAC value that starts from the third section of the CDAC value, may take a start value that removes an overlap section, for example, 0x012C. A3 to AN which are the fourth AFCDAC value to the N^{th} AFCDAC value that respectively start from the fourth to N^{th} sections of the CDAC value may take a start value that removes an overlap section, for example, 0x012C. According to various embodiments as described above, in the state in which the entire DAC slope is maintained, A1=A2= . . . =A(n) or A1≈A2≈ . . . ≈A(n). In other words, by enabling A1 to A(N) to start from a section excluding an overlap section, for example, 0x012C, frequency compensation based on the CDAC value and the AFCDAC value may become linear.

According to an embodiment, when an analog device such as a capacitor is controlled based on a digital value such as a CDAC value and an AFCDAC value, an overlap section may not be completely removed in some cases. Accordingly, the overlap section may be corrected by increasing or decreasing, by a predetermined value, a start value, for example, 0x012 which is obtained by theoretically calculating A1 to A(N), whereby the overlap section may be accurately removed. According to the above-described overlap section correction, A1≈A2≈ . . . ≈A(n), instead of A1=A2= . . . =A(N).

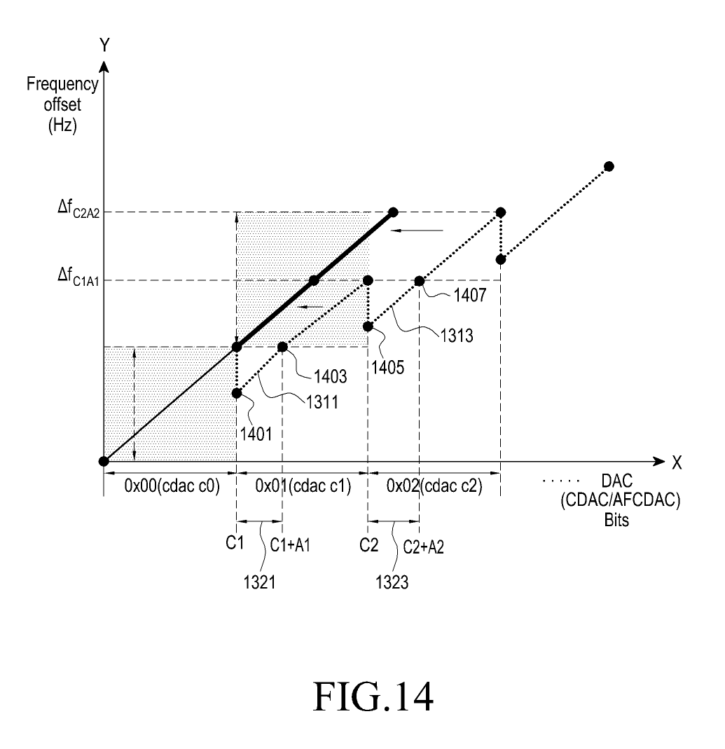

FIG. 14 is a graph illustrating the case in which an electronic device removes a section where compensation frequency values overlap when a CDAC value is changed according to various embodiments.

Referring to FIG. 14, the electronic device may change the start value of an AFCDAC value in the entire section of the AFCDAC value within a CDAC value section in each of the sections 1311 and 1313 where compensation frequency values overlap to an AFCDAC value corresponding to a point that is out of the sections 1321 and 1323 where compensation frequency values overlap, whereby a section where compensation frequency values overlap when the CDAC value is changed may be removed.

For example, by changing a start value 1401 of the AFCDAC value of the entire section of the AFCDAC value within a second CDAC value section (0x01(cdac c1)) in the first section 1311 where compensation frequency values overlap, to an AFCDAC value 1403 corresponding to a point (C1+A1) that is out of the first section 1321 where compensation frequency values overlap, whereby the first section 1311 may be removed. Also, by changing a start value 1405 of the AFCDAC value of the entire section of the AFCDAC value within a third CDAC value section (0x02(cdac c2)) in the second section 1313 where compensation frequency values overlap, to an AFCDAC value 1407 corresponding to a point (C2+A2) that is out of the second section 1323 where compensation frequency values overlap, the first section 1313 may be removed.

Each of the above-described elements described in the present disclosure may be configured with one or more components, and the names of the corresponding elements may vary based on the type of electronic device. The electronic device according to various embodiments may include at least one of the aforementioned elements. Some elements may be omitted or other additional elements may be further included in the electronic device. Also, some of the hardware elements according to various embodiments may be combined into one entity, which may perform functions identical to those of the relevant elements before the combination.

The term “module” as used herein may, for example, mean a unit including one of hardware, software, and firmware or a combination of two or more of them. The “module” may be interchangeably used with, for example, the term “unit”, “logic”, “logical block”, “component”, or “circuit”. The “module” may be a minimum unit of an integrated component or a part thereof. The “module” may be a minimum unit for performing one or more functions or a part thereof. The “module” may be mechanically or electronically implemented. For example, the “module” may include at least one of an application-specific integrated circuit (ASIC) chip, a field-programmable gate arrays (FPGA), and a programmable-logic device for performing operations which have been known or are to be developed hereinafter.

According to various embodiments, at least some of the devices (e.g., modules or functions thereof) or the method (e.g., operations) according to various embodiments may be implemented by an instruction stored in a computer-readable storage medium in a programming module form. The instruction, when executed by a processor (e.g., the processor 120), may cause the one or more processors to execute the function corresponding to the instruction. The computer-readable storage medium may be, for example, the memory 130.

According to various embodiments, a storage medium storing a program is provided. wherein the program in an electronic device performs: determining a delta frequency corresponding to a difference between a first frequency for RF communication and a second frequency outputted from a frequency synthesis unit; and changing capacitances of a first variable capacitor and a second variable capacitor by applying a first control value to a first variable capacitor and applying a second control value to a second variable capacitor, based on the delta frequency.

The computer readable recoding medium may include a hard disk, a floppy disk, magnetic media (e.g., a magnetic tape), optical media (e.g., a Compact Disc Read Only Memory (CD-ROM) and a Digital Versatile Disc (DVD)), magneto-optical media (e.g., a floptical disk), a hardware device (e.g., a Read Only Memory (ROM), a Random Access Memory (RAM), a flash memory), and the like. In addition, the program instructions may include high class language codes, which can be executed in a computer by using an interpreter, as well as machine codes made by a compiler. The aforementioned hardware device may be configured to operate as one or more software modules in order to perform the operation of the present disclosure, and vice versa.

The programming module according to the present disclosure may include one or more of the aforementioned components or may further include other additional components, or some of the aforementioned components may be omitted. Operations executed by a module, a programming module, or other component elements according to various embodiments may be executed sequentially, in parallel, repeatedly, or in a heuristic manner. Furthermore, some operations may be executed in a different order or may be omitted, or other operations may be added.

While the present disclosure has been shown and described with reference to certain embodiments thereof, it will be understood by those skilled in the art that various changes in form and details may be made therein without departing from the spirit and scope of the present disclosure as defined by the appended claims.

What is claimed is:

1. An electronic device, comprising:
a frequency determining circuitry configured to determine a delta frequency corresponding to a difference between a first frequency for RF communication and a second frequency output from a frequency synthesis circuitry;
a digitally-controlled crystal oscillator (DCXO) configured to comprise a plurality of capacitors including a first variable capacitor and a second variable capacitor, and an oscillator connected, directly or indirectly, to the plurality of capacitors and configured to output a clock; and
a processor configured to change capacitances of the first variable capacitor and the second variable capacitor by applying a first control value to the first variable capacitor and applying a second control value to the second variable capacitor, based on the delta frequency.

2. The electronic device of claim 1, wherein the first control value and the second control value are digital bits;
the first control value is set to divide a predetermined compensation frequency range by predetermined bits, and to change a value of the first capacitor by a first capacitance every time the first control value increases by one bit; and
the second control value is set to divide the first control value by predetermined bits, and to change a value of the second capacitor by a second capacitance which is smaller than the first capacitance every time the second control value increases by one bit within the first control value.

3. The electronic device of claim 2, wherein, at a point in time at which the first control value increases by one bit, the processor is configured to change a start bit of the second control value to a bit that is some bits higher than a start bit of the predetermined bits of the second control value.

4. The electronic device of claim 1, further comprising:
a frequency synthesizer configured to output a reference frequency according to a clock of the oscillator.

5. The electronic device of claim 3, wherein, at a point different from the point in time at which the first control value increases by one bit, the processor is configured to apply the start bit of the second control value as the start bit of the predetermined bits of the second control value.

6. An electronic device, comprising:
a frequency synthesis circuitry configured to output a reference frequency for RF transmission/reception modulation;
an RF transceiving module configured to modulate/demodulate an RF transmission/reception signal; and
a baseband module configured to convert data to be transmitted into a baseband signal, provide the baseband signal to the RF transceiving module, and convert a received RF signal into a baseband signal,
wherein the RF transceiving module comprises:
a frequency determining circuitry configured to determine a delta frequency corresponding to a difference between a first frequency for RF communication and a second frequency output from the frequency synthesis unit; and
a digitally-controlled crystal oscillator (DCXO) configured to comprise a plurality of capacitors including a first variable capacitor and a second variable capacitor, and an oscillator connected to the plurality of capacitors and outputting a clock, and
the baseband module comprises: a processor configured to change capacitances of the first variable capacitor and the second variable capacitor by applying a first control value to the first variable capacitor and applying a second control value to the second variable capacitor, based on the delta frequency.

7. The electronic device of claim 6, wherein the first control value and the second control value are digital bits;
the first control value is set to divide a predetermined compensation frequency range by predetermined bits, and to change a value of the first capacitor by a first capacitance every time the first control value increases by one bit; and
the second control value is set to divide the first control value by predetermined bits, and to change a value of the second capacitor by a second capacitance which is smaller than the first capacitance every time the second control value increases by one bit within the first control value.

8. The electronic device of claim 7, wherein, at a point in time at which the first control value increases by one bit, the processor is configured to change a start bit of the second control value to a bit that is some bits higher than a start bit of the predetermined bits of the second control value.

9. The electronic device of claim 6, further comprising:
a frequency synthesizer configured to output a reference frequency according to a clock of the oscillator.

10. The electronic device of claim 8, wherein, at a point different from the point in time at which the first control value increases by one bit, the processor is configured to apply the start bit of the second control value as the start bit of the predetermined bits of the second control value.

11. A method of controlling a digitally-controlled crystal oscillator (DCXO) by an electronic device, the method comprising:
determining a delta frequency corresponding to a difference between a first frequency for RF communication and a second frequency output from a frequency synthesis circuitry; and
changing capacitances of a first variable capacitor and a second variable capacitor by applying a first control value to the first variable capacitor and applying a second control value to the second variable capacitor, based on the delta frequency.

12. The method of claim 11, wherein the first control value and the second control value are digital bits;
the first control value is set to divide a predetermined compensation frequency range by predetermined bits, and to change a value of the first capacitor by a first capacitance every time the first control value increases by one bit; and
the second control value is set to divide the first control value by predetermined bits, and to change a value of the second capacitor by a second capacitance which is smaller than the first capacitance every time the second control value increases by one bit within the first control value.

13. The method of claim 12, further comprising: changing a start bit of the second control value to a bit that is some bits higher than a start bit of the predetermined bits of the second control value at a point in time at which the first control value increases by one bit.

14. The electronic device of claim 12, further comprising:
outputting a reference frequency according the changed capacitances of the first variable capacitor and the second variable capacitor.

15. The method of claim 13, further comprising: applying the start bit of the second control value as the start bit of the predetermined bits of the second control value at a point different from the point in time at which the first control value increases by one bit.

16. A non-transitory storage medium for storing a program, wherein the program in an electronic device is configured to perform:
determining a delta frequency corresponding to a difference between a first frequency for RF communication and a second frequency outputted from a frequency synthesis circuitry; and
changing capacitances of a first variable capacitor and a second variable capacitor by applying a first control value to a first variable capacitor and applying a second control value to a second variable capacitor, based on the delta frequency.
